(19) United States
(12) Patent Application Publication
(10) Pub. No.: US 2009/0156408 A1
(43) Pub. Date: Jun. 18, 2009

(54) HIGH TEMPERATURE SUPERCONDUCTING DIELECTRIC CERAMIC INSULATION

(75) Inventor: William N. Lawless, Westerville, OH (US)

Correspondence Address: DINSMORE & SHOHL LLP, ONE DAYTON CENTRE, ONE SOUTH MAIN STREET, SUITE 1300, DAYTON, OH, 45402-2023, US

(73) Assignee: CERAMPHYSICS, INC., Westerville, OH (US)

(21) Appl. No.: 11/934,439

(22) Filed: Nov. 2, 2007

Related U.S. Application Data
(63) Continuation-in-part of application No. PCT/US2006/016511, filed on Apr. 28, 2006.
(60) Provisional application No. 60/677,521, filed on May 4, 2005.

(51) Int. Cl. H01L 39/06; H01L 39/02

(52) U.S. Cl. 505/166; 505/238; 428/702; 428/336

(57) ABSTRACT

High-temperature superconductive devices and assemblies are provided. According to one embodiment, a high-temperature superconductive device includes a superconducting substrate and a dielectric ceramic insulator. The superconducting substrate comprises a superconducting material having superconductive properties above about 60 K. The dielectric ceramic insulator is applied to the superconducting substrate. The dielectric ceramic insulator comprises a thermal conductivity of at least about 0.2 W/cm-K at a temperature ranging from about 60 K to about 90 K and has a grain size of at least about 2 microns. Additional embodiments are disclosed and claimed.

### CROSS-REFERENCE TO RELATED APPLICATIONS

The present application is filed under 35 U.S.C. 111(a) as a continuation-in-part of international patent application no. PCT/US2006/016511 (LAE 0034 PB), filed Apr. 28, 2006, which international application designates the United States and claims the benefit of U.S. Provisional Application Ser. No. 60/677,521 (LAE 0034 MA), filed May 4, 2005.

### TECHNICAL FIELD

The present invention relates to high-temperature superconductive devices and assemblies. More particularly, the present invention relates to assemblies which include magnets, motors, or generators wound with high-temperature superconducting wires and tapes coated with dielectric ceramic insulators.

### BACKGROUND OF THE INVENTION

Magnets, motors and generators wound with high-temperature superconducting wires and tapes are of great interest for a variety of applications, including use in both military and commercial applications. Conventional applications have generally utilized magnets which were operated in superconducting states at temperatures ranging from 20-30 K. Such conventional applications require refrigeration systems that are large and heavy, and thus inefficient and costly. If magnets were placed in superconducting environments operating near 77 K this would relieve most of these refrigeration penalties, however quench protection would become a secondary issue at these higher temperatures.

Quench protection prevents a magnet from self-destructing during use in a superconductive environment. During operation often a portion, or zone, of the superconductor wound around the magnet will lose its superconductivity and become resistive at this “normal” zone. Due to the large electrical current, this normal zone will rapidly increase in temperature, thus causing neighboring regions to heat and also become normal zones. This propagation of normal zones can ultimately destroy the magnet. As such, a quench protection mechanism is needed to prevent such a failure from taking place.

Quench protection becomes increasingly important as the temperature is increased from 20-30 K to 77 K because the thermal diffusivity of the superconductor decreases and the quench propagation velocity slows to a few cm/sec, causing the magnet energy to be discharged rapidly into a small volume, thereby possibly destroying the magnet. Thus, improved methods of quench protection are needed to allow a superconductor to operate at higher temperatures (above 30 K) in order to minimize refrigeration size and weight.

### SUMMARY OF THE INVENTION

According to one embodiment, a high-temperature superconductive device includes a superconducting substrate and a dielectric ceramic insulator. The superconducting substrate comprises a superconducting material having superconductive properties above about 60 K. The dielectric ceramic insulator is applied to the superconducting substrate. The dielectric ceramic insulator comprises a thermal conductivity of at least about 0.2 W/cm-K at a temperature ranging from about 60 K to about 90 K and has a grain size of at least about 2 microns.

According to another embodiment, a high-temperature superconductive assembly includes a superconducting substrate, a dielectric ceramic insulator and a superconductive structure. The superconducting substrate comprises a superconducting material in the form of a tape or wire having superconductive properties above about 60 K. The dielectric ceramic insulator is applied to the superconducting substrate. The dielectric ceramic insulator comprises ZnO, or in the alternative, Zn₂GeO₄. The superconductive structure consists of a magnet, motor or generator and is adapted to be wound with the superconducting substrate to provide quench protection.

### BRIEF DESCRIPTION OF THE DRAWINGS

The following detailed description of specific embodiments of the present invention can be best understood when read in conjunction with the following figures, where like structure is indicated with like reference numerals and in which:

FIG. 1 illustrates a perspective view of an embodiment showing a portion of a high-temperature superconductive device having a superconducting substrate including a superconducting material, and a dielectric ceramic insulator;

FIG. 2 is a graph showing thermal conductivity of ZnO and Zn₂GeO₄ in units of Watts/(centimeter-K) as a function of temperature in units of Kelvin;

FIG. 3 is a graph showing thermal diffusivity of ZnO and Zn₂GeO₄ in units of centimeter²/second as a function of temperature in units of Kelvin; and

FIG. 4 depicts a perspective view of an embodiment of a high-temperature superconductive assembly including a magnet wound with a superconductive device similar to that of FIG. 1.

### DETAILED DESCRIPTION

Generally various embodiments of the present invention relate to high-temperature superconductive devices and assemblies. Such high-temperature superconductive devices and assemblies are directed for use in environments requiring less refrigeration than low-temperature superconducting systems (20 K -30 K) thus providing more efficient and less costly options for a variety of uses and applications.

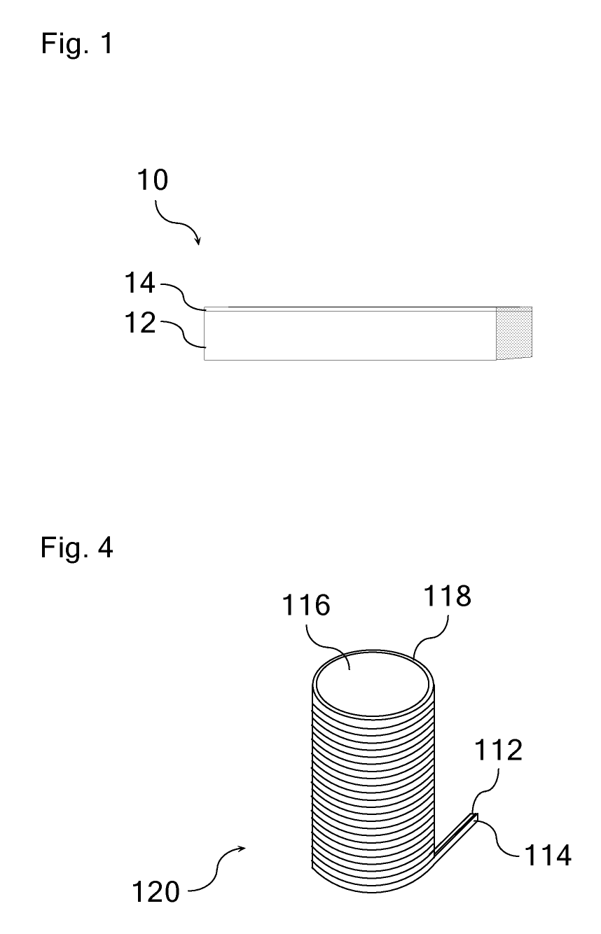

Referring initially to FIG. 1, one embodiment of the present invention includes a high-temperature superconductive device which has a superconducting substrate 12 and a dielectric ceramic insulator 14. The superconducting substrate 12 includes a superconducting material which has superconductive properties above about 60 K. More particularly, the superconducting material has superconductive properties at or near 77 K. The superconducting substrate 12 may include other components as well as the superconducting material. The superconducting substrate 12 may take on a multitude of forms, but in particular, the superconducting substrate 12 can be in the form of a wire or tape so that the superconducting substrate 12 is adapted to be wound around a superconductive structure (see FIG. 4), such as a magnet, motor or generator.

The dielectric ceramic insulator 14 is applied to the superconducting substrate 12 and can be done so through a variety of methods. For example, such applications can include applying the dielectric ceramic insulator 14 to the superconducting substrate 12 by sputtering, ion-beam-assisted sputtering, pulsed laser deposition, or chemical vapor deposition. The dielectric ceramic insulator 14 has a thermal conductivity of at least about 0.2 W/cm-K at every temperature in a range from about 60 K to about 90 K. This large thermal conductivity in such a temperature range provides quench protection for the superconducting material in the high-temperature superconducting environment. For example, heat generated in a normal zone of the superconducting material will dissipate efficiently through the dielectric ceramic insulator, thus preventing the normal zone on the superconducting material from propagating, and thus destroying the superconductor.

In addition to the thermal conductive qualities of the dielectric ceramic insulator 12, such insulators 12 utilized in the high-temperature superconductive device 10 as shown in FIG. 1 can also have a grain size of at least about 2 microns. Generally, ceramic insulators have thermal conductivities below 0.2 W/cm-K at temperatures ranging from 60 K to 90 K due in large part to the concept of boundary-scattering. Phonons (i.e., lattice waves) are the heat carriers in dielectric materials, and as temperature is decreased, the wavelengths for the phonons, which are strongly temperature dependent, become increasingly longer and the thermal conductivity increases accordingly. A temperature is eventually reached, however, where the wavelengths are constrained from increasing further by the physical size, or boundaries, of the sample. At this point the wavelengths lose their temperature dependence and the thermal conductivity rapidly decreases. In the case of a single crystal, the physical dimension of the crystal determines the boundary-scattering limit, and particularly in the case of a ceramic, the grain size determines the boundary-scattering limit. Thus, providing a dielectric ceramic insulator with a grain size of at least about 2 microns or a thickness of at least about 2 microns can provide sufficient size to offset such boundary-scattering limitations.

According to one embodiment of the present invention, two dielectric ceramic insulators, ZnO and Zn₂GeO₄, can be used as part of the high-temperature superconductive device because these dielectric ceramic insulators have large thermal conductivities at lower temperatures in general and more specifically near 77 K. Thus, both ZnO and Zn₂GeO₄ provide sufficient quench protection to the superconducting material so that the superconducting material can operate at higher temperatures (i.e., 60 K to 90 K), thus minimizes refrigeration size and weight.

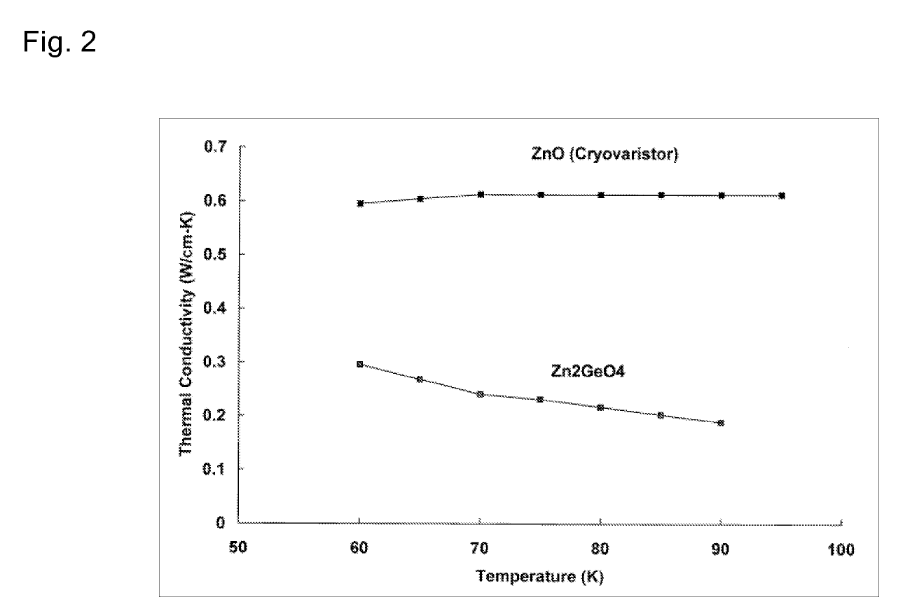

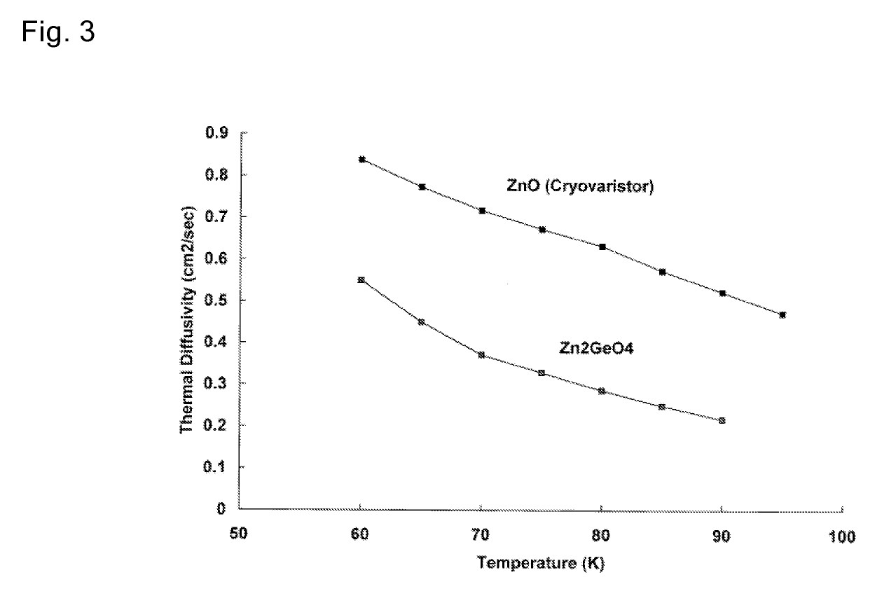

FIGS. 2 and 3 illustrate thermal conductivity and thermal diffusivity properties of both ZnO and Zn₂GeO₄ at temperatures ranging from about 60 K to about 90 K. FIG. 2 shows a relationship between thermal conductivity in units of W/(cm-K) as a function of temperature in units of Kelvin for ZnO, as well as showing the same relationship for Zn₂GeO₄. FIG. 3 shows a relationship between thermal diffusivity in units of centimeter²/second as a function of temperature in units of Kelvin for ZnO, as well as showing the same relationship for Zn₂GeO₄.

It is important to note that the data for ZnO in the FIGS. 2 and 3 are actually measured for a doped ZnO, or otherwise known as a cryovaristor ZnO, where the dopants are in the grain boundaries and impart a varistor characteristic at cryogenic temperatures. However, it is known that the data in the figures also apply to pure ZnO as well. For example, a study was made which compares pure ZnO ceramic insulators and cryovaristor ZnO ceramic insulators (See W. N. Lawless and T. K. Gupta, J. Appl. Phys. 60, 607 (1986)) wherein thermal properties were measured below 30 K to research the basic physics of these materials. It was discovered that the thermal properties of both the pure and doped ZnO were different only below about 20 K. Thus, the dopants in the grain boundaries do not affect the thermal properties above about 30 K, and certainly would not at temperatures ranging from 60 K to 90 K, including near 77 K. As such, the dielectric ceramic insulator 14 as shown in FIG. 1 could further include a dopant. For example, such a dopant could include Bi₂O₃.

Referring now to FIG. 4, another embodiment of the present invention illustrates a high-temperature superconductive assembly 120 which can include a similar high-temperature superconductive device 10 as illustrated in FIG. 1. The high-temperature superconductive assembly 120 includes a superconducting substrate 112, a dielectric ceramic insulator 114 and a superconductive structure 116. The superconducting substrate 112 comprises a superconducting material in the form of a tape or wire having superconductive properties above about 60 K. The dielectric ceramic insulator 114 is applied to the superconducting substrate 112. The dielectric ceramic insulator 114 includes ZnO, or in the alternative, Zn₂GeO₄. The superconductive structure 116 consists of a magnet, motor or generator and is adapted to be wound with the superconducting substrate 112 to provide quench protection. As illustrated in FIG. 4, the superconductive structure 116 includes a magnet 118 which is wound with a superconducting substrate 112 coated with a dielectric ceramic insulator 114 to provide quench protection. Although the superconductive substrate 112 is illustrated in FIG. 4 as a superconductive tape coated on one side by the insulator 114, it is contemplated that the tape may be coated on both major faces, or on all sides, by the insulator 114.

It is noted that terms like “preferably,” commonly,” and “typically,” when utilized herein, should not be read to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

Having described the invention in detail and by reference to specific embodiments thereof, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A high-temperature superconductive device comprising:
a superconducting substrate comprising a superconducting material having superconductive properties above 60 K; and
a dielectric ceramic insulator applied to the superconducting substrate, wherein the dielectric ceramic insulator comprises a thermal conductivity of at least about 0.2 W/cm-K at a temperature ranging from about 60 K to about 90 K, wherein the dielectric ceramic insulator further comprises a grain size of at least about 2 microns.

2. The high-temperature superconductive device of claim 1, wherein the dielectric ceramic insulator comprises ZnO, or in the alternative, Zn₂GeO₄.

3. The high-temperature superconductive device of claim 1, wherein the superconducting substrate is in the form of a tape or wire.

4. The high-temperature superconductive device of claim 3, wherein the superconducting substrate is adapted to be wound around a superconductive structure.

5. The high-temperature superconductive device of claim 4, wherein the superconductive structure consists of a magnet, motor, or generator.

6. The high-temperature superconductive device of claim 3, wherein the dielectric ceramic insulator provides quench protection to a superconductive structure.

7. The high-temperature superconductive device of claim 1, wherein the dielectric ceramic insulator is applied to the superconducting substrate by sputtering, ion-beam-assisted sputtering, pulsed laser deposition, or chemical vapor deposition.

8. The high-temperature superconductive device of claim 1, wherein the dielectric ceramic insulator further comprises a dopant.

9. A high-temperature superconductive assembly comprising:
a superconducting substrate comprising a superconducting material in the form of a tape or wire having superconductive properties above 60 K;
a dielectric ceramic insulator applied to the superconducting substrate, wherein the dielectric ceramic insulator comprises ZnO, or in the alternative, Zn₂GeO₄; and
a superconductive structure consisting of a magnet, motor or generator and which is adapted to be wound with the superconducting substrate to provide quench protection.

10. The high-temperature superconductive assembly of claim 9, wherein the assembly is operated near 77 K.

11. The high-temperature superconductive assembly of claim 9, wherein the dielectric ceramic insulator has a grain size of at least about 2 microns.

12. The high-temperature superconductive assembly of claim 9, wherein the dielectric ceramic insulator is applied to the superconducting substrate having a thickness of at least about 2 microns.
